(19) United States
(12) Patent Application Publication
(10) Pub. No.: US 2026/0262206 A1
(43) Pub. Date: Sep. 3, 2026

(54) CONDUCTIVE NONWOVEN FABRIC, PRETREATMENT METHOD FOR CONDUCTIVE NONWOVEN FABRIC, METHOD FOR MANUFACTURING CONDUCTIVE NONWOVEN FABRIC, METHOD FOR MANUFACTURING CONDUCTIVE NONWOVEN FABRIC TAPE, AND METHOD FOR MANUFACTURING WIRE HARNESS

(71) Applicant: Yazaki Corporation, Tokyo (JP)

(72) Inventor: Satoko HONGO, Shizuoka (JP)

(73) Assignee: Yazaki Corporation, Tokyo (JP)

(21) Appl. No.: 19/530,675

(22) Filed: Feb. 5, 2026

(30) Foreign Application Priority Data
Feb. 28, 2025 (JP) 2025-031226

(51) Int. Cl. H05K 9/00; C09J 7/22; D06M 11/83; H01B 1/02; H01B 5/00; H01B 13/00; H01B 13/012

(52) U.S. Cl. CPC H05K 9/0098; C09J 7/22; D06M 11/83; H01B 1/02; H01B 5/00; H01B 13/0036; H01B 13/01263; C09J 2400/163; C09J 2400/263; D06M 2200/00

(57) ABSTRACT

A conductive nonwoven fabric includes a nonwoven fabric, and a plated portion made of a conductive metal and covered with fibers constituting the nonwoven fabric. The weight per unit area of the plated portion is 30 g/m² or more and 96 g/m² or less.

### CROSS-REFERENCE TO RELATED APPLICATIONS

This application is based on and claims priority under 35 USC 119 from Japanese Patent Application No. 2025-031226 filed on Feb. 28, 2025, the entire content of which is incorporated herein by reference.

### TECHNICAL FIELD

The present disclosure relates to a conductive nonwoven fabric, a pretreatment method for a conductive nonwoven fabric, a method for manufacturing a conductive nonwoven fabric, a method for manufacturing a conductive nonwoven fabric tape, and a method for manufacturing a wire harness.

### BACKGROUND ART

In the related art, a cable has been proposed in which a conductive nonwoven fabric including a nonwoven fabric and a plated portion made of a conductive metal and covered with fibers constituting the nonwoven fabric, is disposed on the outer periphery of an electric wire, for example, see WO2023/074771. In the cable, while an electromagnetic shielding effect is exhibited by the plated portion of the conductive nonwoven fabric, the nonwoven fabric is relatively excellent in expansion and compression due to characteristics of the material and can follow the bending of the electric wire. In particular, in the conductive nonwoven fabric of the cable, a value obtained by dividing an electrical resistance value of a surface layer by an electrical resistance value of an intermediate layer at an intermediate position in a thickness direction is set to 4.0 or less, a predetermined amount or more of the conductive metal is ensured for the intermediate layer, and the shielding effect can be appropriately exhibited.

However, the conductive nonwoven fabric described in WO2023/074771 becomes too hard when a large amount of the conductive metal is plated, and causes problems such as the conductive nonwoven fabric being difficult to wind around the electric wire, and the conductive nonwoven fabric being opened even when being wound around the electric wire. On the other hand, when the amount of the plated portion is too small, the amount of the conductive metal is small, so that the shielding effect cannot be appropriately exhibited.

The present disclosure has been made to solve such problems in the related art, and an object of the present disclosure is to provide a conductive nonwoven fabric that can be favorably provided on an electric wire and can appropriately exhibit a shielding effect, a pretreatment method for a conductive nonwoven fabric, a method for manufacturing a conductive nonwoven fabric, a method for manufacturing a conductive nonwoven fabric tape, and a method for manufacturing a wire harness.

### SUMMARY OF INVENTION

A conductive nonwoven fabric includes a nonwoven fabric, and a plated portion made of a conductive metal and covered with fibers constituting the nonwoven fabric. The weight per unit area of the plated portion is 30 g/m² or more and 96 g/m² or less.

A pretreatment method for a conductive nonwoven fabric, includes: preparing a nonwoven fabric having a thickness of 0.30 mm or more and 1.00 mm or less and the weight per unit volume of 0.2 g/cm³ or more and 0.4 g/cm³ or less; charging the nonwoven fabric prepared into a treatment tank into which an organometallic complex soluble in carbon dioxide in a supercritical state is charged; supplying the carbon dioxide in the supercritical state to the treatment tank into which the nonwoven fabric is charged, and setting inside of the treatment tank to an environment having a pressure of 12 MPa or more and 15 MPa or less and a temperature of 100° C. or more and 130° C. or less; and taking out, after the carbon dioxide in the supercritical state is supplied and the environment is set, the nonwoven fabric from the treatment tank after a time of 10 minutes or more and 60 minutes or less.

According to the present disclosure, it is possible to favorably provide the conductive nonwoven fabric on the electric wire and to appropriately exhibit a shielding effect.

### BRIEF DESCRIPTION OF DRAWINGS

FIG. 1 is a perspective view illustrating a wire harness according to an embodiment of the present disclosure;

FIGS. 2A and 2B are cross-sectional views illustrating details of a conductive nonwoven fabric tape illustrated in FIG. 1, in which FIG. 2A illustrates a cross section orthogonal to a longitudinal direction of the tape, and FIG. 2B illustrates a partial enlarged diagram of FIG. 2A;

FIG. 3 is a schematic view for explaining a plating pretreatment method according to the present embodiment;

FIG. 4 is a chart illustrating examples and comparative examples;

FIG. 5 is a configuration diagram illustrating an example of the conductive nonwoven fabric after half-wrap winding; and

FIG. 6 is a graph illustrating shielding performances of conductive nonwoven fabrics according to the examples and the comparative examples.

### DESCRIPTION OF EMBODIMENTS

Hereinafter, the present disclosure will be described with reference to a preferred embodiment. The present disclosure is not limited to the following embodiment, and may be appropriately modified without departing from the gist of the present disclosure. In the embodiment to be described below, there may be parts in which illustration and description of a part of a configuration are omitted, and it is needless to say that a publicly known or well-known technique is appropriately applied to details of an omitted technique within a range in which no contradiction with contents to be described below would occur.

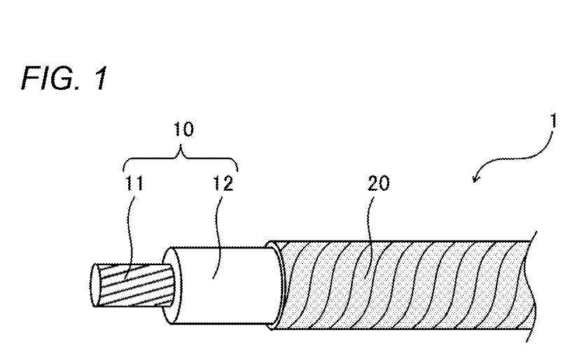

FIG. 1 is a perspective view illustrating a wire harness according to an embodiment of the present disclosure. As illustrated in FIG. 1, a wire harness 1 according to the present embodiment includes an electric wire 10 and a conductive nonwoven fabric tape 20 wound in a spiral shape around the electric wire 10 in a half-wrap winding manner.

The electric wire 10 includes a conductor 11 made of, for example, copper, aluminum, or an alloy thereof, and an insulating sheath portion 12 covering the conductor 11. The conductor 11 of the electric wire 10 according to the present embodiment may be a twisted wire formed by twisting a plurality of conductive element wires, or may be a single wire. The sheath portion 12 is made of polyvinyl chloride (PVC), polypropylene (PP), polyethylene (PE), or the like. However, the sheath portion 12 is not limited to the above, and may be made of silicone, polyurethane, nylon, or the like. The number of electric wires 10 in the example of FIG. 1 is one, but the number thereof is not limited to one, and may be two or more.

Although not illustrated, the wire harness 1 including such an electric wire 10 may include, for example, a connector at a terminal portion, and tape winding using a resin tape may be performed on a part of the wire harness 1 within a range in which attachment achieved by adhesion to be described later is not hindered. In addition, the wire harness 1 may include another member, which is not limited to the connector and the resin tape.

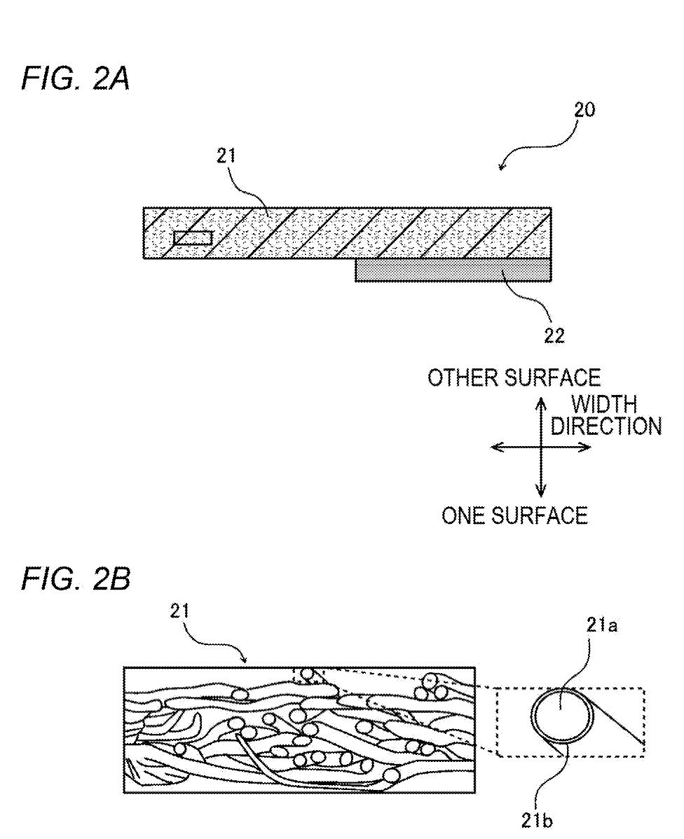

FIGS. 2A and 2B are cross-sectional views illustrating details of the conductive nonwoven fabric tape 20 illustrated in FIG. 1, in which FIG. 2A illustrates a cross section orthogonal to a longitudinal direction of the tape, and FIG. 2B illustrates a partial enlarged diagram of FIG. 2A. As illustrated in FIG. 2A, the conductive nonwoven fabric tape 20 includes a conductive nonwoven fabric 21 and an adhesive layer 22 provided on a surface (a front surface or a back surface) of the conductive nonwoven fabric 21.

As illustrated in FIG. 2B, the conductive nonwoven fabric 21 includes a nonwoven fabric 21a, and a plated portion 21b. The nonwoven fabric 21a is a sheet-shaped member in which fibers are intertwined without being woven. As illustrated in FIG. 2B, the fibers of the nonwoven fabric 21a are formed as multiple layers in a thickness direction in terms of manufacturing characteristics. The fibers constituting the nonwoven fabric 21a are made of, for example, polyethylene terephthalate (PET), PP, nylon, acrylic, glass fiber, carbon fiber, aramid fiber, polyarylate fiber, or the like.

The plated portion 21b is a conductive metal covering the fibers constituting the nonwoven fabric 21a. The plated portion 21b is made of, for example, copper, nickel, tin, silver, or an alloy of these metals. The plated portion 21b may be formed in a single layer on the fibers constituting the nonwoven fabric 21a, or may be formed in a plurality of layers. Therefore, the plated portion 21b may be formed, for example, as copper (a first layer) and tin (a second layer) on the fibers constituting the nonwoven fabric 21a.

The adhesive layer 22 is made of a material or the like that exhibits an adhesive force, and the material is not particularly limited. The adhesive layer 22 is provided on at least one surface of the conductive nonwoven fabric 21 illustrated in FIG. 2A. In the present embodiment, the adhesive layer 22 is formed at only one end (an example of the part) of the one surface in a width direction so as to correspond to half-wrap winding of the conductive nonwoven fabric tape 20. The adhesive layer 22 is not limited to being formed at only one end of the conductive nonwoven fabric 21, and may be formed at only a central portion thereof, or may be formed in a plurality of streaks along the longitudinal direction, and the form thereof is not limited.

Further, in the conductive nonwoven fabric 21 of the conductive nonwoven fabric tape 20 used in the wire harness 1 according to the present embodiment, the weight per unit area of the plated portion 21b is 30 g/m² or more. In the conductive nonwoven fabric 21, the weight per unit area of the plated portion 21b is 96 g/m² or less.

Here, as a result of intensive discussion by the inventor of the application, it has been found that the conductive nonwoven fabric 21 does not sufficiently exhibit a shielding effect when the weight per unit area of the plated portion 21b is less than 30 g/m², and becomes hard and is difficult to wind around the electric wire 10 when the weight per unit area of the plated portion 21b exceeds 96 g/m².

That is, when the weight per unit area of the plated portion 21b is less than 30 g/m², the weight of the plated portion 21b of the conductive nonwoven fabric 21 is small, and thus the amount of the metal sufficient to block noise cannot be secured. On the other hand, when the weight per unit area of the plated portion 21b exceeds 96 g/m², the metal used for the plated portion 21b of the conductive nonwoven fabric 21 is excessive, and the conductive nonwoven fabric 21 becomes hard due to the excessive metal.

Therefore, in the conductive nonwoven fabric 21 according to the present embodiment, the weight per unit area of the plated portion 21b is 30 g/m² or more and 96 g/m² or less. Here, in order to achieve such weight of the plated portion 21b, it is necessary to optimize a fiber density (the weight per unit volume) of the nonwoven fabric 21a and the thickness of the nonwoven fabric 21a before the conductive nonwoven fabric 21 is plated.

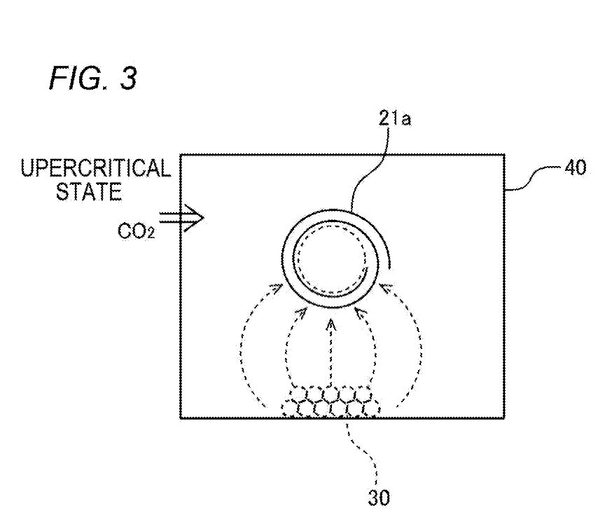

Next, a pretreatment method for the conductive nonwoven fabric 21 according to the present embodiment, and methods for manufacturing the conductive nonwoven fabric 21, the conductive nonwoven fabric tape 20, and the wire harness 1 will be described. FIG. 3 is a schematic view for explaining a plating pretreatment method according to the present embodiment.

In order to manufacture the conductive nonwoven fabric 21 in which the weight of the plated portion 21b is optimized as described above, the nonwoven fabric 21a having a thickness of 0.30 mm or more and 1.00 mm or less and the weight per unit volume of 0.2 g/cm³ or more and 0.4 g/cm³ or less is prepared (a first step).

Next, the nonwoven fabric 21a is charged into a housing (a treatment tank) 40 into which an organometallic complex 30 shown in FIG. 3 is charged (a second step). At this time, the nonwoven fabric 21a is stored in a state of being wound, for example, two rounds around a cylindrical bobbin provided in the housing 40. As the organometallic complex 30, a substance soluble in carbon dioxide in a supercritical state, such as palladium and nickel, is charged.

After the storage, the carbon dioxide in the supercritical state is supplied to the housing 40 (a third step). The inside of the housing 40 is set to an environment having a pressure of 12 MPa or more and 15 MPa or less and a temperature of 100° C. or more and 130° C. or less due to the supply of the carbon dioxide in the supercritical state. A circulation flow rate of the carbon dioxide in the supercritical state during the treatment is 0.5 kg/min or more and 8 kg/min or less.

By such a treatment, the organometallic complex 30 is dissolved in an oil agent on the fibers constituting the nonwoven fabric 21a via the carbon dioxide in the supercritical state and then is reduced, and the organometallic complex 30 is decomposed and deposited on a surface of the fibers constituting the nonwoven fabric 21a or the like.

Next, after a predetermined time (for example, after a time of 10 minutes or more and 60 minutes or less) since the inside of the housing 40 is set to the environment described above, the nonwoven fabric 21a is taken out from the housing 40 (a fourth step). Accordingly, the pretreatment of the conductive nonwoven fabric 21 is completed.

Thereafter, the oil agent is removed. At this time, for example, a heating treatment is performed at 150° C. or higher (250° C. or higher depending on the heat resistance of the fibers) for 60 minutes or longer. By this treatment, the oil agent on the fibers is removed, and a metal deposited on the fibers is activated.

Next, an electroless plating treatment is performed on the nonwoven fabric 21a from which the oil agent is removed and on which the metal is activated (a fifth step). For example, copper is used as a plating metal. Accordingly, the conductive nonwoven fabric 21 in which the weight of the plated portion 21b is optimized as described above can be manufactured.

Thereafter, as illustrated in FIGS. 2A and 2B, for example, the adhesive layer 22 is formed on the one surface of the conductive nonwoven fabric 21 (a sixth step). Accordingly, the conductive nonwoven fabric tape 20 is manufactured. The adhesive layer 22 may be formed, for example, by attaching a double-sided tape or by providing a chemical layer such as an adhesive.

Next, the conductive nonwoven fabric tape 20 is wound around the electric wire 10 (a seventh step). Accordingly, the wire harness 1 as illustrated in FIG. 1 is manufactured.

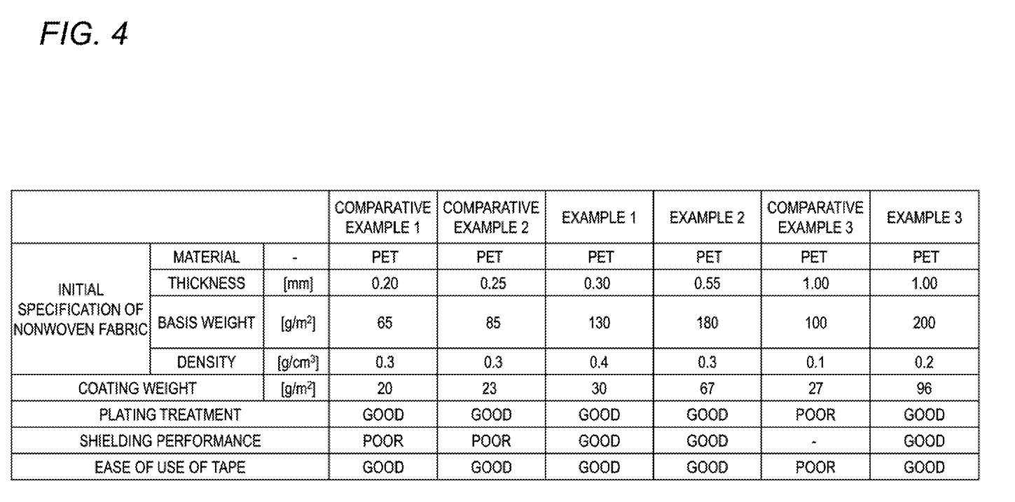

Next, Examples and Comparative Examples will be described. FIG. 4 is a chart illustrating Examples and Comparative Examples. Conductive nonwoven fabrics illustrated in Examples 1 to 3 and Comparative Examples 1 to 3 in FIG. 4 were manufactured by the above manufacturing method (the manufacturing method in which conditions were unified), and regarding all the nonwoven fabrics, the material was PET, and the plating metal was copper.

Regarding Comparative Example 1, an initial specification of the nonwoven fabric refers to a thickness of 0.20 mm, a basis weight of 65 g/m², and a density (the weight per unit volume) of 0.3 g/cm³. An initial specification for Comparative Example 2 refers to a thickness of 0.25 mm, a basis weight of 85 g/m², and a density of 0.3 g/cm³, and an initial specification for Example 1 refers to a thickness of 0.30 mm, a basis weight of 130 g/m², and a density of 0.4 g/cm³. An initial specification for Example 2 refers to a thickness of 0.55 mm, a basis weight of 180 g/m², and a density of 0.3 g/cm³, and an initial specification for Comparative Example 3 refers to a thickness of 1.00 mm, a basis weight of 100 g/m², and a density of 0.1 g/cm³. An initial specification for Example 3 refers to a thickness of 1.00 mm, a basis weight of 200 g/m², and a density of 0.2 g/cm³.

As a result of performing copper plating on the nonwoven fabrics having such initial specifications, a coating weight was 20 g/m² in Comparative Example 1, 23 g/m² in Comparative Example 2, and 30 g/m² in Example 1. In addition, the coating weight was 67 g/m² in Example 2, 27 g/m² in Comparative Example 3, and 96 g/m² in Example 3.

These Examples and Comparative Examples were evaluated from three viewpoints, that is, the plating treatment, the shielding performance, and the ease of use of the tape. Regarding the plating treatment, it was evaluated whether the thickness of the nonwoven fabric obtained by applying the pressure to the nonwoven fabric having the initial specification due to the carbon dioxide in the supercritical state in the pretreatment, is too thin with respect to the initial thickness. Each of Examples and Comparative Examples was evaluated as "good" when a thickness of 50% or more with respect to the initial thickness was maintained, and was evaluated as "poor" when a thickness less than 50% with respect to the initial thickness was obtained. This is because the nonwoven fabric becomes hard and is difficult to wind when the thickness is too thin.

Regarding the shielding performance, it was evaluated whether the conductive nonwoven fabric exhibits a shielding effect of 30 dB or more in a frequency band of 100 kHz or more and 1 GHz or less in which the shielding effect is generally recognized. Each of Examples and Comparative Examples was evaluated as "good" when the shielding effect of 30 dB or more was exhibited in the entire frequency band of 100 kHz or more and 1 GHz or less, and was evaluated as "poor" when only a shielding effect less than 30 dB was exhibited in the frequency band of 100 kHz or more and 1 GHz or less.

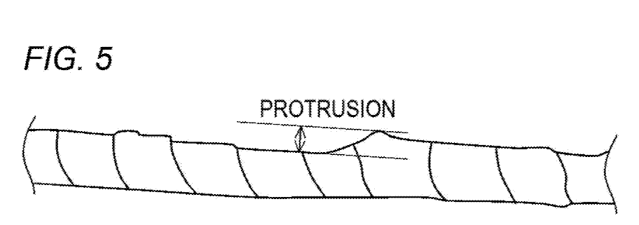

Regarding the ease of use of the tape, it was evaluated whether the tape can be wound around the electric wire with less unevenness. The ease of use of the tape was evaluated by forming the adhesive layer on the conductive nonwoven fabric and performing the half-wrap winding. The adhesive layer is formed by attaching a double-sided tape having a thickness of 50 μm only on one end of the one surface corresponding to the half-wrap winding. FIG. 5 is a configuration diagram illustrating an example of the conductive nonwoven fabric after the half-wrap winding. As illustrated in FIG. 5, each of Examples and Comparative Examples was evaluated as "good" when a protrusion, which shows an unevenness difference in a radial direction of the electric wire, was less than 2 mm, and was evaluated as "poor" when the protrusion was 2 mm or more. The large protrusion indicates that the conductive nonwoven fabric is hard and cannot be appropriately wound.

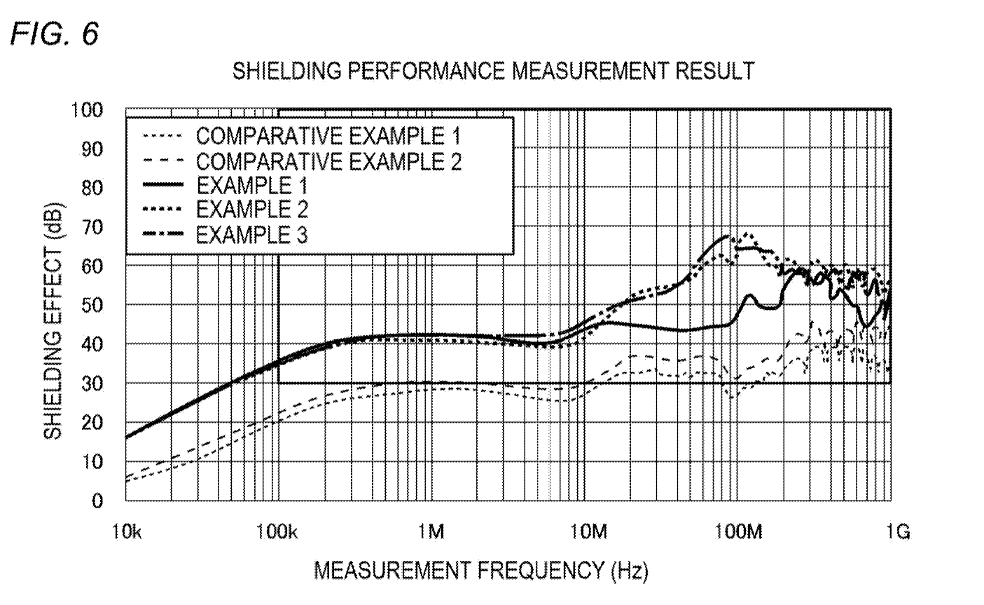

First, the conductive nonwoven fabric and the conductive nonwoven fabric tape according to Comparative Example 1 were evaluated as "good" in terms of the plating treatment and the ease of use of the tape, but were evaluated as "poor" in terms of the shielding performance. FIG. 6 is a graph illustrating the shielding performances of the conductive nonwoven fabrics according to Examples and Comparative Examples. FIG. 6 does not illustrate Comparative Example 3. As illustrated in FIG. 6, the conductive nonwoven fabric according to Comparative Example 1 exhibited the shielding effect of 30 dB or more only in a frequency band of 15 MHz or more and 80 MHz or less and in a frequency band of 150 MHz or more.

Further, the conductive nonwoven fabric and the conductive nonwoven fabric tape according to Comparative Example 2 were evaluated as "good" in terms of the plating treatment and the ease of use of the tape, but were evaluated as "poor" in terms of the shielding performance. As illustrated in FIG. 6, the conductive nonwoven fabric according to Comparative Example 2 exhibited the shielding effect of 30 dB or more only in a frequency band of 10 MHz or more.

The conductive nonwoven fabric and the conductive nonwoven fabric tape according to Comparative Example 3 were evaluated as "poor" in terms of the plating treatment. In particular, the conductive nonwoven fabric according to Comparative Example 3 was compressed to about 1/3 of the thickness described above by the pretreatment, and single yarns were agglutinated to each other, so that the conductive nonwoven fabric became very hard. Therefore, it was difficult to wind the conductive nonwoven fabric according to Comparative Example 3 to be in close contact with the electric wire, and when the conductive nonwoven fabric was forcibly wound, many creases or plating cracks of the nonwoven fabric and many protrusions of the nonwoven fabric from the electric wire occurred, and it was difficult to measure the shielding effect. Therefore, the conductive nonwoven fabric and the conductive nonwoven fabric tape according to Comparative Example 3 were evaluated as "poor" in terms of the ease of use of the tape, and the shielding performance thereof was evaluated as "-" indicating that measurement could not be performed.

On the other hand, the conductive nonwoven fabric and the conductive nonwoven fabric tape according to Example 1 were evaluated as "good" in terms of the plating treatment, the shielding performance, and the ease of use of the tape. In particular, regarding the shielding performance, as illustrated in FIG. 6, the shielding effect of 30 dB or more was exhibited in a frequency band of 50 kHz or more. Similarly, the conductive nonwoven fabric and the conductive nonwoven fabric tape according to each of Example 2 and Example 3 were evaluated as "good" in terms of the plating treatment, the shielding performance, and the ease of use of the tape, and exhibited the shielding effect of 30 dB or more in the frequency band of 50 kHz or more.

As described above, the conductive nonwoven fabric and the conductive nonwoven fabric tape were evaluated as "poor" in terms of any one of the plating treatment, the shielding performance, and the ease of use of the tape in Comparative Examples 1 to 3, and the conductive nonwoven fabric and the conductive nonwoven fabric tape were evaluated as "good" in terms of the plating treatment, the shielding performance, and the ease of use of the tape in Examples 1 to 3. Therefore, it was found that there were differences in performance between the conductive nonwoven fabrics and the conductive nonwoven fabric tapes depending on the initial specifications of the nonwoven fabrics. In particular, it was found that in the initial specification of the nonwoven fabric, the thickness and the density were likely to affect the coating weight at the time of forming the plated portion, and the optimum initial specification of the nonwoven fabric referred to a thickness of 0.30 mm or more and 1.00 mm or less and a density of 0.2 g/cm³ or more and 0.4 g/cm³ or less.

In this way, in the conductive nonwoven fabric 21 according to the present embodiment, the weight per unit area of the plated portion 21b is 30 g/m² or more and 96 g/m² or less. Therefore, the amount of the conductive metal as the plated portion 21b is optimized, the conductive nonwoven fabric 21 becomes too hard when the amount of the metal excessively increases, and the amount of the metal is less likely to decrease as the shielding effect becomes insufficient. Thus, it is possible to provide the conductive nonwoven fabric 21 that can be favorably provided on the electric wire 10 and can appropriately exhibit the shielding effect.

In addition, according to the pretreatment method for the conductive nonwoven fabric 21 of the present embodiment, the nonwoven fabric 21a having the thickness of 0.30 mm or more and 1.00 mm or less and the density of 0.2 g/cm³ or more and 0.4 g/cm³ or less in an initial state is prepared, and the plating pretreatment is performed to the nonwoven fabric 21a by using the carbon dioxide in the supercritical state to dissolve the organometallic complex 30. Therefore, the appropriate conductive nonwoven fabric 21 can be obtained by using the nonwoven fabric 21a subjected to the pretreatment. Thus, it is possible to provide the pretreatment method for the conductive nonwoven fabric 21 that can be favorably provided on the electric wire 10 and can appropriately exhibit the shielding effect.

In addition, according to the conductive nonwoven fabric 21, the conductive nonwoven fabric tape 20, or the wire harness 1 of the present embodiment, it is possible to provide a method for manufacturing the conductive nonwoven fabric 21 that can be favorably provided on the electric wire 10 and can appropriately exhibit the shielding effect, a method for manufacturing the conductive nonwoven fabric tape 20, or a method for manufacturing the wire harness 1.

Although the present disclosure has been described above based on the embodiment, the present disclosure is not limited to the embodiment described above, and modifications may be made without departing from the gist of the present disclosure. Although the electroless plating treatment was performed in Examples, an electrolytic plating treatment may be performed after the electroless plating treatment, and publicly known or well-known techniques may be appropriately combined if possible.

For example, in the present embodiment, the wire harness 1 includes the electric wire 10 and the conductive nonwoven fabric tape 20. However, the present disclosure is not limited thereto, and the wire harness 1 may further include other elements, for example, an exterior member such as a corrugated tube and another electric wire outside the conductive nonwoven fabric tape 20.

In addition, the conductive nonwoven fabric tape 20 is wound around the electric wire 10 in a half-wrap winding manner, but the present disclosure is not particularly limited to the half-wrap winding.

What is claimed is:

1. A conductive nonwoven fabric, comprising:
a nonwoven fabric; and
a plated portion made of a conductive metal and covered with fibers constituting the nonwoven fabric,
wherein the weight per unit area of the plated portion is 30 g/m² or more and 96 g/m² or less.

2. A pretreatment method for a conductive nonwoven fabric, comprising:
preparing a nonwoven fabric having a thickness of 0.30 mm or more and 1.00 mm or less and the weight per unit volume of 0.2 g/cm³ or more and 0.4 g/cm³ or less;
charging the nonwoven fabric into a treatment tank into which an organometallic complex soluble in carbon dioxide in a supercritical state is charged;
supplying the carbon dioxide in the supercritical state to the treatment tank into which the nonwoven fabric is charged, and setting inside of the treatment tank to an environment having a pressure of 12 MPa or more and 15 MPa or less and a temperature of 100° C. or more and 130° C. or less; and
taking out, after the carbon dioxide in the supercritical state is supplied and the environment is set, the nonwoven fabric from the treatment tank after a time of 10 minutes or more and 60 minutes or less.

3. A method for manufacturing a conductive nonwoven fabric, comprising:
performing metal plating by using an electroless plating treatment on the nonwoven fabric taken out from the treatment tank in the pretreatment method for a conductive nonwoven fabric according to claim 2, to obtain the conductive nonwoven fabric.

4. A method for manufacturing a conductive nonwoven fabric tape, comprising:
forming an adhesive layer on the conductive nonwoven fabric obtained in the method for manufacturing a conductive nonwoven fabric according to claim 3.

5. A method for manufacturing a wire harness, comprising:
winding the conductive nonwoven fabric tape obtained by forming the adhesive layer in the method for manufacturing a conductive nonwoven fabric tape according to claim 4, around an electric wire.
